(19) United States
(12) Patent Application Publication
(10) Pub. No.: US 2022/0293614 A1
(43) Pub. Date: Sep. 15, 2022

(54) NONVOLATILE MEMORY DEVICE WITH AN ERASE GATE OVERHANG AND INTEGRATION SCHEMES

(71) Applicant: GLOBALFOUNDRIES Singapore Pte. Ltd., Singapore (SG)

(72) Inventors: XINSHU CAI, Singapore (SG); SHYUE SENG TAN, Singapore (SG); KIOK BOONE ELGIN QUEK, Singapore (SG)

(21) Appl. No.: 17/198,145

(22) Filed: Mar. 10, 2021

(51) Int. Cl. H01L 27/11521; H01L 29/423; G11C 16/04; H01L 29/788; H01L 29/66

(52) U.S. Cl. CPC H01L 27/11521; H01L 29/42328; G11C 16/0408; H01L 29/788; H01L 29/66825

(57) ABSTRACT

A nonvolatile memory device is provided. The nonvolatile memory device comprises a floating gate arranged below a control gate, and between an erase gate and a word line. A first side portion of the floating gate and a second side portion of the floating gate may extend laterally beyond the control gate in substantially equal amounts. The erase gate may overhang the first side portion of the floating gate. A first control gate spacer may be arranged between the control gate and the word line. The first control gate spacer may at least partially cover a top surface of the second side portion of the floating gate.

### FIELD OF THE INVENTION

The disclosed embodiments relate generally to nonvolatile memory devices, and more particularly, to nonvolatile memory devices with an erase gate overhang and integration schemes.

### BACKGROUND

A nonvolatile memory device retains stored data even if power is turned off. An example of a nonvolatile memory device includes electrically erasable programmable read only memory (EEPROM) and flash EEPROM. In typical flash memory architecture, a floating gate may be used to store charges. The floating gate may be arranged over an active region such as a p-well. A control gate may be arranged above the floating gate. A word line or select gate may be arranged next to the floating gate. An erase gate may be arranged next to the floating gate and opposite to the word line. A source region may be arranged below the erase gate. A drain region may be laterally displaced from the word line.

During an erase operation, a voltage may be applied to the erase gate. The charges stored in the floating gate may tunnel through a tunnel dielectric layer to the erase gate. A portion of the erase gate may overhang the floating gate to enhance erase performance. The erase gate overhang may be fabricated using a sacrificial floating gate spacer process with a high temperature oxide (HTO). However, the high temperature oxide process is expensive. Removing the high temperature oxide process may eliminate the erase gate overhang and leads to poor erase performance. Thus, there is a need to overcome the challenges mentioned above.

### SUMMARY

In an aspect of the present disclosure, a nonvolatile memory device is provided. The nonvolatile memory device comprises a floating gate arranged below a control gate, and between an erase gate and a word line. A first side portion of the floating gate and a second side portion of the floating gate may extend laterally beyond the control gate in substantially equal amounts. The erase gate may overhang the first side portion of the floating gate. A first control gate spacer may be arranged between the control gate and the word line. The first control gate spacer may at least partially cover a top surface of the second side portion of the floating gate.

In another aspect of the present disclosure, a nonvolatile memory device is provided. The nonvolatile memory device comprises a floating gate arranged below a control gate, and between an erase gate and a word line. A first side portion of the floating gate and a second side portion of the floating gate may extend laterally beyond the control gate in substantially equal amounts. The erase gate may overhang a top surface of the first side portion of the floating gate. A first control gate spacer may be arranged between the control gate and the word line. The first control gate spacer may at least partially cover a top surface of the second side portion of the floating gate. A floating gate dielectric spacer may be arranged between the floating gate and the word line.

In yet another aspect of the present disclosure, a method of fabricating a nonvolatile memory device is provided. The method comprises providing a floating gate below a control gate, whereby a first side portion of the floating gate and a second side portion of the floating gate extend laterally beyond the control gate in substantially equal amounts. A first control gate spacer may be formed adjacent to the control gate, whereby the first control gate spacer at least partially covers a top surface of the second side portion of the floating gate. An erase gate may be formed overhanging the first side portion of the floating gate. A word line may be formed next to the floating gate and the first control gate spacer.

Numerous advantages may be derived from the embodiments described below. The embodiments provide a nonvolatile memory device with an erase gate overhanging the floating gate, leading to a good erase performance. An overlap amount between the erase gate and the floating gate may be varied. The nonvolatile memory device may be fabricated using an economical fabrication process without additional masking steps.

### BRIEF DESCRIPTION OF THE DRAWINGS

The disclosed embodiments will be better understood from a reading of the following detailed description, taken in conjunction with the accompanying drawings:

FIG. 1 illustrates a cross-section view of a nonvolatile memory device, according to an embodiment of the disclosure.

FIG. 2 illustrates a cross-section view of a nonvolatile memory device, according to another embodiment of the disclosure.

FIGS. 3A to 3E illustrate a fabrication process flow for the nonvolatile memory device shown in FIG. 1, according to some embodiments of the disclosure.

FIGS. 4A to 4C illustrate a fabrication process flow for the nonvolatile memory device shown in FIG. 2, according to some embodiments of the disclosure.

For simplicity and clarity of illustration, the drawings illustrate the general manner of construction, and certain descriptions and details of well-known features and techniques may be omitted to avoid unnecessarily obscuring the discussion of the described embodiments of the devices. Additionally, elements in the drawings are not necessarily drawn to scale. For example, the dimensions of some of the elements in the drawings may be exaggerated relative to other elements to help improve understanding of embodiments of the devices. The same reference numerals in different drawings denote the same elements, while similar reference numerals may, but do not necessarily, denote similar elements.

### DETAILED DESCRIPTION

The following detailed description is exemplary in nature and is not intended to limit the devices or the application and uses of the devices. Furthermore, there is no intention to be bound by any theory presented in the preceding background of the devices or the following detailed description.

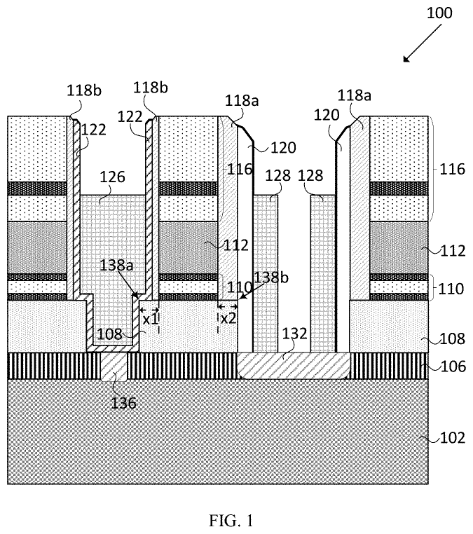

FIG. 1 illustrates a cross-section view of a nonvolatile memory device 100, according to an embodiment of the disclosure. The nonvolatile memory device 100 includes a substrate 102 with an active region 106 in an upper portion of the substrate 102.

The substrate 102 may be made of silicon or any other suitable semiconductor material. The active region 106 may be doped p-type to form a p-well. The nonvolatile memory device 100 may include a floating gate 108, a control gate 112, an erase gate 126 and a word line 128. The floating gate 108, the erase gate 126 and the word line 128 may be arranged above the active region 106. Although not shown, one dielectric layer may separate the floating gate 108 and another dielectric layer separates the word line 128 from the active region 106, to prevent charge transfer between the active region 106 and the floating gate 108, and between the active region 106 and the word line 128, respectively. The control gate 112 may be arranged above the floating gate 108. A dielectric stack 110 may be arranged between the control gate 112 and the floating gate 108. In one embodiment, the dielectric stack 110 may be made of an oxide/nitride/oxide (ONO) or any other suitable dielectric materials. A dielectric stack 116 may be arranged above the control gate 112. The dielectric stack 116 may be made of silicon dioxide (SiO₂) or silicon nitride (Si₃N₄). A first side portion 138a of the floating gate 108 may extend laterally beyond the control gate 112 by a distance x1. A second side portion 138b of the floating gate 108 may extend laterally beyond the control gate 112 by a distance x2. In one embodiment, x1 may be substantially equal to x2. In another embodiment, x1 and x2 may not be equal. The first side portion 138a may be opposite to the second side portion 138b. The term “floating gate” may refer to a gate electrode that is electrically isolated from an input terminal and may be capacitively coupled to the input terminal. There may not be direct current flowing from the input terminal to the floating gate during a reading operation. In one embodiment, the input terminal may be the control gate 112.

The erase gate 126 may be arranged next to the first side portion 138a of the floating gate 108. The term “erase gate” may refer to a gate electrode that is electrically insulated from the floating gate 108 and may receive charges from the floating gate 108 during an erase operation. A side portion of the erase gate 126 may extend laterally over the first side portion 138a of the floating gate 108, thereby overhanging the floating gate 108. A lower portion of the erase gate 126 may extend vertically against a side surface of the first side portion 138a of the floating gate 108. As such, the erase gate 126 is in contact with a top surface and a side surface of the first side portion 138a of the floating gate 108, presenting a large surface area for charge transfer between the floating gate 108 and the erase gate 126. The word line 128 may be arranged next to the second side portion 138b of the floating gate 108. A first control gate spacer 118a may be arranged between the control gate 112 and the word line 128. In one embodiment, the first control gate spacer 118a may at least partially cover a top surface of the second side portion 138b of the floating gate 108. In another embodiment, the first control gate spacer 118a may completely cover the top surface of the second side portion 138b of the floating gate 108. In one embodiment, the first control gate spacer 118a may be made of a suitable dielectric material, for example silicon nitride (Si₃N₄), silicon dioxide (SiO₂), any other suitable dielectric material or their combination.

A second control gate spacer 118b may be arranged next to a side surface of the control gate 112, opposite to the first control gate spacer 118a. The second control gate spacer 118b may be arranged between the control gate 112 and the erase gate 126. In one embodiment, the second control gate spacer 118b may be thinner than the first control gate spacer 118a. The second control gate spacer 118b may cover a portion of the top surface of the first side portion 138a of the floating gate 108. In one embodiment, the second control gate spacer 118b may be made of a suitable dielectric material, for example silicon nitride (Si₃N₄), silicon dioxide (SiO₂), any other suitable dielectric material or their combination. In one embodiment, the first control gate spacer 118a and the second control gate spacer 118b may be made of the same dielectric material. In another embodiment, the first control gate spacer 118a may be made of a different dielectric material from the second control gate spacer 118b. The first 118a and the second 118b control gate spacers may protect side surfaces of the control gate 112 from moisture or chemicals and may electrically insulate the control gate 112 from the word line 128 and the erase gate 126, respectively.

A tunnel dielectric layer 122 may cover a remaining portion of the top surface of the first side portion 138a of the floating gate 108, next to the second control gate spacer 118b. The tunnel dielectric layer 122 may extend over a side surface of the first side portion 138a of the floating gate 108 and a top surface of the active region 106. The erase gate 126 may be arranged over the tunnel dielectric layer 122. The tunnel dielectric layer 122 may be arranged between the erase gate 126 and the first side portion 138a of the floating gate 108.

A floating gate spacer 120 may be arranged between the floating gate 108 and the word line 128. The floating gate spacer 120 may be adjacent to the first control gate spacer 118a. The floating gate spacer 120 may uniformly cover the first control gate spacer 118a and the floating gate 108. In one embodiment, the floating gate spacer 120 may cover a side surface of the second side portion 138b of the floating gate 108. The floating gate spacer 120 may be made of a suitable dielectric material, for example, silicon dioxide (SiO₂) or any other suitable dielectric material. In a preferred embodiment, the floating gate spacer 120 may be made of a different dielectric material from the first control gate spacer 118a. The floating gate spacer 120 is used to protect the floating gate 108 during a subsequent source region 136 formation.

A source region 136 may be arranged in the active region 106, under the tunnel dielectric layer 122 and the erase gate 126. In one embodiment, the source region 136 may be n-doped. A word line threshold implant region 132 may be arranged in the active region 106, below the word line 128. Although not shown, an n⁺ drain region may be formed in the word line threshold implant region 132 after formation of the word line 128. The word line threshold implant region 132 may provide a suitable threshold voltage or on-voltage for the non-volatile memory device 100. In one embodiment, the word line threshold implant region 132 may be p-doped.

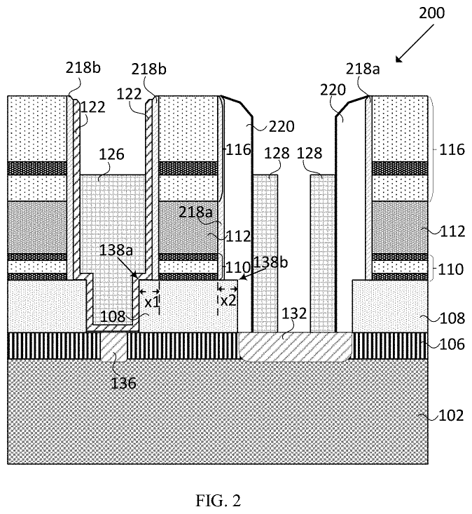

FIG. 2 illustrates a cross-section view of a nonvolatile memory device 200, according to another embodiment of the disclosure. Like reference numerals in FIG. 1 refer to like features in FIG. 2. In contrast to the nonvolatile memory device 100 shown in FIG. 1, the nonvolatile memory device 200 may include a first control gate spacer 218a and a second control gate spacer 218b, whereby the first 218a and the second 218b control gate spacers have approximately equal thicknesses. The first 218a and the second 218b control gate spacers may cover a portion of a top surface of a first side portion 138a and a second 138b side portion of a floating gate 108, respectively. A floating gate spacer 220 may be arranged over the top surface of the second side portion 138b of the floating gate 108, adjacent to the first control gate spacer 218a. The floating gate spacer 220 may extend over a side surface of the floating gate 108, thereby separating the floating gate 108 from a word line 128. In a preferred embodiment, the floating gate spacer 220 may uniformly cover the side surface of the second side portion 138b of the floating gate 108.

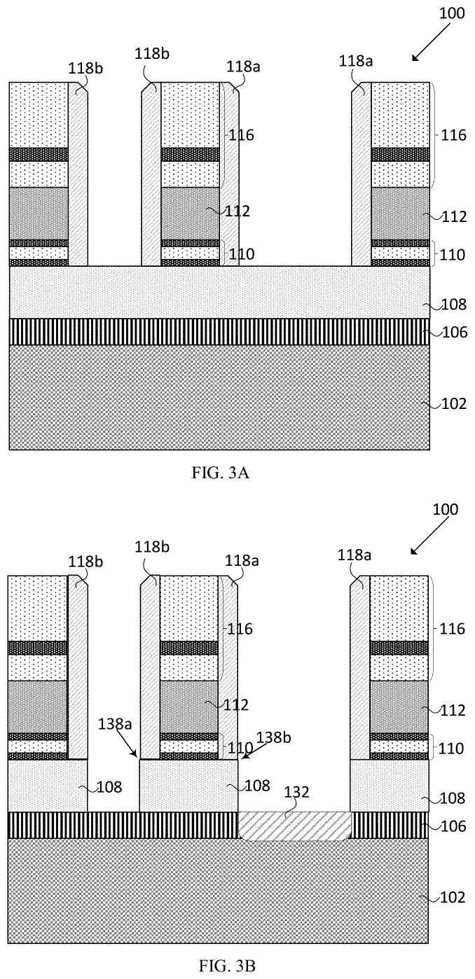

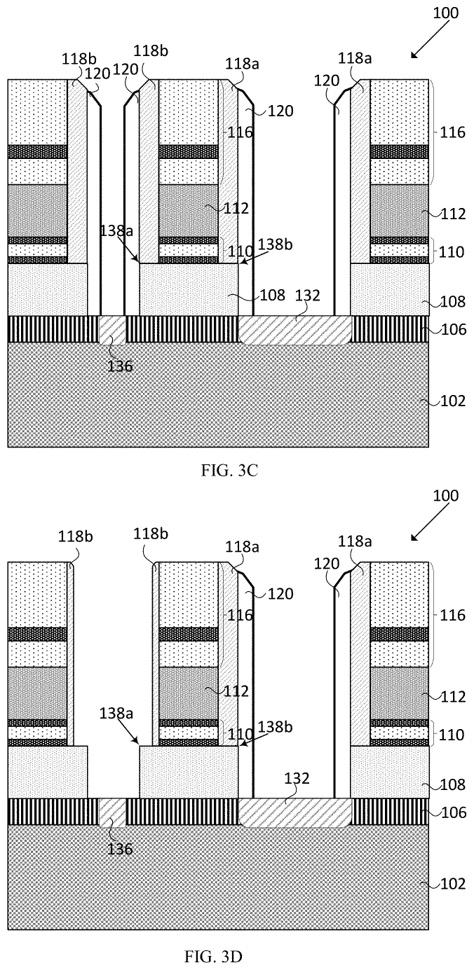

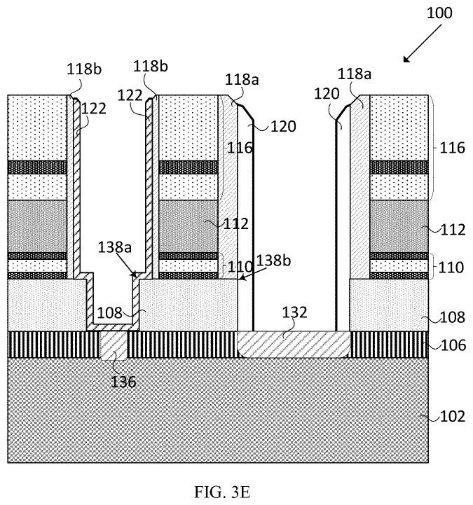

FIGS. 3A to 3E illustrate a fabrication process flow for the nonvolatile memory device 100 shown in FIG. 1, according to some embodiments of the disclosure. FIG. 3A illustrates a cross-section view of a partially completed nonvolatile memory device 100 after formation of a first 118a and a second 118b control gate spacers, according to an embodiment of the disclosure. Referring to FIG. 3A, a floating gate 108 layer arranged below a control gate 112 may be provided. In one embodiment, the floating gate 108 layer may be made of n-doped polysilicon. A dielectric stack 110 may be arranged between the floating gate 108 layer and the control gate 112. A dielectric stack 116 may be arranged above the control gate 112. Although not shown, a dielectric layer may be provided between the floating gate 108 layer and an active region 106 of a substrate 102. A first 118a and a second 118b control gate spacers may be formed over first and second side surfaces, respectively, of the dielectric stacks 110 and 116 and the control gate 112. The first 118a control gate spacer may be formed opposite to the second 118b control gate spacer. The formation of the first 118a and the second 118b control gate spacers may include depositing a layer of a suitable dielectric material, for example, silicon nitride (Si₃N₄), silicon dioxide (SiO₂), any other suitable dielectric material or their combination by a suitable deposition process, for example atomic layer deposition (ALD), chemical vapor deposition (CVD), physical vapor deposition (PVD), or any other suitable deposition processes. The silicon nitride layer may be patterned by an anisotropic etching process to leave behind a portion of the silicon nitride layer over a side surface of the dielectric stacks 110 and 116 and the control gate 112. The term “anisotropic etching” may refer to an etching process that is directional in nature.

FIG. 3B illustrates a cross-section view of a partially completed nonvolatile memory device 100 after patterning the floating gate 108 layer and formation of a word line threshold implant region 132, according to an embodiment of the disclosure. Referring to FIG. 3B, the word line threshold implant region 132 may be formed by implanting a portion of the active region 106 laterally displaced from the first control gate spacer 118a with a suitable p-type dopant, for example, boron (B), boron difluoride (BF₂), or any other suitable p-type dopant. Although not shown, an implant mask may be used to cover the control gate 112 and a portion of the active region 106 laterally displaced from the second control gate spacer 118b during the implantation process. An activation annealing may be used to activate the implanted dopants. The floating gate layer may be patterned by a wet etch or dry etch process to form a floating gate 108 having a first side portion 138a and a second side portion 138b. The first side portion 138a of the floating gate 108 may be formed below the second 118b control gate spacer. The second side portion 138b of the floating gate 108 may be formed below the first 118a control gate spacer. The first side portion 138a and the second side portion 138b of the floating gate 108 may extend laterally beyond the control gate 112 in substantially equal amounts. Although not shown, the dielectric layer between the floating gate 108 and the active region 106 may extend across a top surface of the active region 106 providing electrical insulation for a subsequently formed word line 128.

FIG. 3C illustrates a cross-section view of a partially completed nonvolatile memory device 100 after formation of a floating gate spacer 120 and a source region 136, according to an embodiment of the disclosure. The floating gate spacer 120 may be formed by depositing a layer of a suitable dielectric material, for example, silicon dioxide over the first 118a and second 118b control gate spacers and the floating gate 108. The deposition of the silicon dioxide layer may be by a suitable deposition process, for example atomic layer deposition (ALD), chemical vapor deposition (CVD), physical vapor deposition (PVD), or any other suitable deposition processes. The silicon dioxide layer may be patterned by an anisotropic etching process to form the floating gate spacer 120 over a side surface of the first 118a and second 118b control gate spacers and the floating gate 108. The source region 136 may be formed by implanting a suitable n-type dopant, for example phosphorus, arsenic or any other suitable n-type dopant in the active region 106, laterally displaced from the floating gate spacer 120 adjacent to the second control gate spacer 118b. In another embodiment, the source region 136 may be laterally displaced from the floating gate 108. Although not shown, a photoresist layer may be used as an implant mask to cover the dielectric stack 116, the first control gate spacer 118a, the floating gate spacer 120 adjacent to the first control gate spacer 118a and the word line threshold implant region 132 during the implantation process.

FIG. 3D illustrates a cross-section view of a partially completed nonvolatile memory device 100 after removal of the floating gate spacer 120 adjacent to the second control gate spacer 118b and patterning of the second control gate spacer 118b, according to an embodiment of the disclosure. Referring to FIG. 3D, the floating gate spacer 120 adjacent to the second control gate spacer 118b may be removed by a wet etch or dry etch process. The second control gate spacer 118b may be patterned by a wet etch or dry etch process to expose part of the first side portion 138a of the floating gate 108. The patterning process may leave behind a portion of the second control gate spacer 118b over a side surface of the control gate 112. In one embodiment, the portion of the second control gate spacer 118b may be thinner than the first control gate spacer 118a. The removal of the floating gate spacer 120 and patterning of the second control gate spacer 118b may use the same implant mask as for the formation of the source region 136, resulting in cost savings. The implant mask may be subsequently removed. The removal of the floating gate spacer 120 and patterning of the second control gate spacer 118b may be referred to as a pre-clean process prior to a tunnel dielectric layer 122 formation.

FIG. 3E illustrates a cross-section view of a partially completed nonvolatile memory device 100 after formation of a tunnel dielectric layer 122, according to an embodiment of the disclosure. The tunnel dielectric layer 122 may be formed by depositing a layer of a suitable dielectric material, for example, silicon dioxide, hafnium dioxide (HfO₂), or any other suitable dielectric material over the source region 136 and a portion of an adjacent active region 106, the first side portion 138a of the floating gate 108 and a side surface of the second control gate spacer 118b. The deposition process may be by atomic layer deposition, chemical vapor deposition, physical vapor deposition or any other suitable deposition processes.

The process continues to form the nonvolatile memory device 100 shown in FIG. 1. Referring back to FIG. 1, a layer of a suitable conductive material, for example, polysilicon or any other suitable conductive material, may be deposited over the tunnel dielectric layer 122 and the portion of the word line threshold implant region 132 adjacent to the floating gate spacer 120 to thereby form the erase gate 126 and the word line 128, respectively. In one embodiment, the photoresist layer may be removed in a lift-off process, thereby removing the conductive material from the dielectric stack 116, the first 118a and second 118b control gate spacers, the floating gate spacer 120 and a portion of the word line threshold implant region 132.

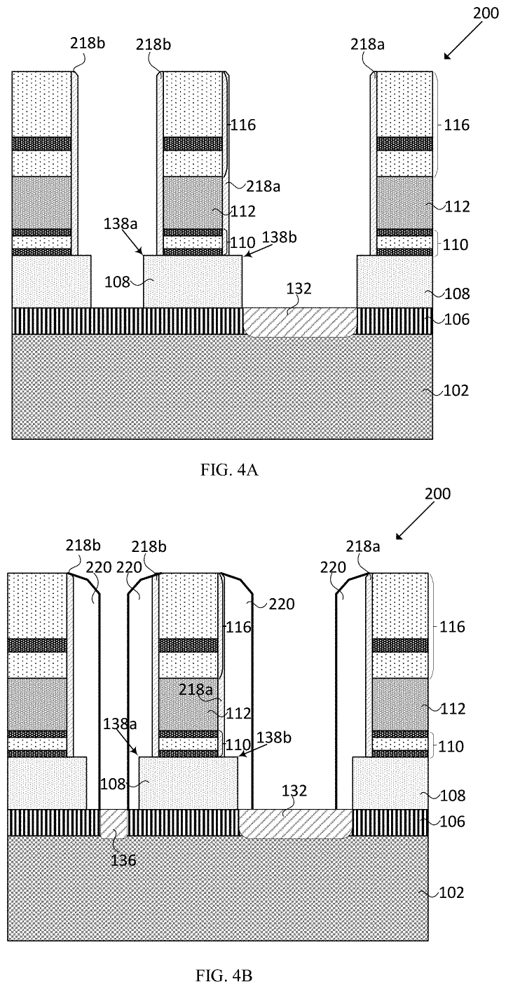

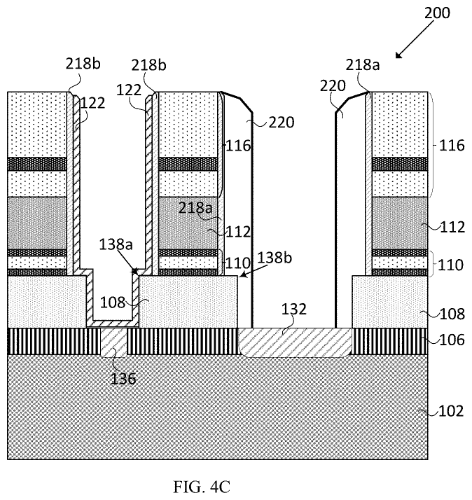

FIGS. 4A to 4C illustrate a fabrication process flow for the nonvolatile memory device 200 shown in FIG. 2, according to some embodiments of the disclosure. FIG. 4A illustrates a cross-section view of a partially completed nonvolatile memory device 200 after formation of a floating gate 108 having a first side portion 138a and a second side portion 138b, a first 218a and a second 218b control gate spacers and a word line threshold implant region 132, according to an embodiment of the disclosure. The formation of the floating gate 108, the first 218a and the second 218b control gate spacers and the word line threshold implant region 132 may follow the fabrication process outlined in FIGS. 3A and 3B. The first 218a and the second 218b control gate spacers may be patterned by a wet etch or dry etch process to expose part of the second side portion 138b and the first side portion 138a of the floating gate 108, respectively. The etching process may not need any masking layer. The first 218a and the second 218b control gate spacers may have substantially equal thicknesses due to the etching process.

FIG. 4B illustrates a cross-section view of a partially completed nonvolatile memory device 200 after formation of a floating gate spacer 220 and a source region 136, according to an embodiment of the disclosure. Referring to FIG. 4B, the formation of the floating gate spacer 220 may include deposition of a layer of suitable dielectric material, for example, silicon dioxide or any other suitable dielectric material, over a side surface of the first 218a and the second 218b control gate spacers and the first side portion 138a and the second side portion 138b of the floating gate 108. In one embodiment, the floating gate spacer 220 may cover part of a top surface of the first side portion 138a and the second side portion 138b of the floating gate 108. The formation of the source region 136 may be similar to the formation of the source region 136 illustrated in FIG. 3C.

FIG. 4C illustrates a cross-section view of a partially completed nonvolatile memory device 200 after removal of the floating gate spacer 220 from the second control gate spacer 218b and the first side portion 138a of the floating gate 108 and formation of a tunnel dielectric layer 122, according to an embodiment of the disclosure. Referring to FIG. 4C, the removal of the floating gate spacer 220 from the second control gate spacer 218b and the first side portion 138a of the floating gate 108 may be by a wet etch or dry etch process. The first side portion 138a of the floating gate 108 may be exposed after the removal process. The tunnel dielectric layer 122 may be formed over the exposed first side portion 138a of the floating gate 108. The formation of the tunnel dielectric layer 122 may be similar to the process outlined in FIG. 3E.

The process continues to form the nonvolatile memory device 200 shown in FIG. 2. Referring to FIG. 2, an erase gate 126 may be formed over the tunnel dielectric layer 122 and a word line 128 may be formed adjacent to the floating gate spacer 220. The formation of the erase gate 126 and the word line 128 may be similar to the process outlined in FIG. 1.

The terms “first”, “second”, “third”, and the like in the description and in the claims, if any, are used for distinguishing between similar elements and not necessarily for describing a particular sequential or chronological order. It is to be understood that the terms so used are interchangeable under appropriate circumstances such that the embodiments of the device described herein are, for example, capable of operation in sequences other than those illustrated or otherwise described herein. The terms “left”, “right”, “front”, “back”, “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device.

While several exemplary embodiments have been presented in the above detailed description of the device, it should be appreciated that number of variations exist. It should further be appreciated that the embodiments are only examples, and are not intended to limit the scope, applicability, dimensions, or configuration of the devices in any way. Rather, the above detailed description will provide those skilled in the art with a convenient road map for implementing an exemplary embodiment of the devices, it being understood that various changes may be made in the function and arrangement of elements and method of fabrication described in an exemplary embodiment without departing from the scope of this disclosure as set forth in the appended claims.

What is claimed:

1. A nonvolatile memory device comprising:
a floating gate below a control gate, and between an erase gate and a word line, wherein a first side portion of the floating gate and a second side portion of the floating gate extend laterally beyond the control gate in substantially equal amounts;
the erase gate overhangs the first side portion of the floating gate; and
a first control gate spacer between the control gate and the word line, wherein the first control gate spacer at least partially covers a top surface of the second side portion of the floating gate.

2. The nonvolatile memory device of claim 1, wherein the first control gate spacer completely covers the top surface of the second side portion of the floating gate.

3. The nonvolatile memory device of claim 1, further comprising:
a second control gate spacer between the control gate and the erase gate.

4. The nonvolatile memory device of claim 3, wherein the second control gate spacer is thinner than the first control gate spacer.

5. The nonvolatile memory device of claim 3, further comprising:
a tunnel dielectric layer between the erase gate and the floating gate, wherein the tunnel dielectric layer covers a top surface of the first side portion of the floating gate.

6. The nonvolatile memory device of claim 5, wherein the tunnel dielectric layer is adjacent to the second control gate spacer.

7. The nonvolatile memory device of claim 1, further comprising:
a floating gate spacer between the floating gate and the word line.

8. The nonvolatile memory device of claim 7, wherein the floating gate spacer is adjacent to the first control gate spacer.

9. The nonvolatile memory device of claim 8, wherein the floating gate spacer and the first control gate spacer are made of different materials.

10. The nonvolatile memory device of claim 5, wherein the erase gate is over the top surface of the first side portion of the floating gate.

11. A nonvolatile memory device comprising:
a floating gate below a control gate, and between an erase gate and a word line, wherein a first side portion of the floating gate and a second side portion of the floating gate extend laterally beyond the control gate in substantially equal amounts;
the erase gate overhangs a top surface of the first side portion of the floating gate;
a first control gate spacer between the control gate and the word line, wherein the first control gate spacer at least partially covers a top surface of the second side portion of the floating gate; and
a floating gate dielectric spacer between the floating gate and the word line.

12. The nonvolatile memory device of claim 11, wherein the first control gate spacer completely covers the top surface of the second side portion of the floating gate.

13. The nonvolatile memory device of claim 11, wherein the floating gate dielectric spacer is over the top surface of the second side portion of the floating gate.

14. The nonvolatile memory device of claim 11, further comprising:
a second control gate spacer between the control gate and the erase gate.

15. The nonvolatile memory device of claim 14, wherein the second control gate spacer is thinner than the first control gate spacer.

16. The nonvolatile memory device of claim 11, wherein the first control gate spacer and the floating gate dielectric spacer are made of different dielectric materials.

17. The nonvolatile memory device of claim 11, wherein the floating gate dielectric spacer uniformly covers the first control gate spacer and the floating gate.

18. The nonvolatile memory device of claim 17, wherein the floating gate dielectric spacer uniformly covers a side surface of the second side portion of the floating gate.

19. A method of fabricating a nonvolatile memory device, the method comprising:
providing a floating gate below a control gate, wherein a first side portion of the floating gate and a second side portion of the floating gate extend laterally beyond the control gate in substantially equal amounts;
forming a first control gate spacer adjacent to the control gate, wherein the first control gate spacer at least partially covers a top surface of the second side portion of the floating gate;
forming an erase gate overhanging the first side portion of the floating gate;
and
forming a word line next to the floating gate and the first control gate spacer.

20. The method of claim 19, wherein providing the floating gate below the control gate further comprises:
forming the first control gate spacer over a first side surface of the control gate and a second control gate spacer over a second side surface of the control gate;
forming the first side portion of the floating gate below the second control gate spacer and the second side portion of the floating gate below the first control gate spacer, wherein the first side portion of the floating gate and the second side portion of the floating gate extend laterally beyond the control gate in substantially equal amounts.
